(19) United States
(12) Patent Application Publication
(10) Pub. No.: US 2024/0186467 A1
(43) Pub. Date: Jun. 6, 2024

(54) INTEGRATING COLOR CONVERSION MATERIAL IN A MICRODEVICE

(71) Applicant: VueReal Inc., Waterloo (CA)

(72) Inventors: Gholamreza CHAJI, Waterloo (CA); Ehsanollah FATHI, Waterloo (CA)

(73) Assignee: VueReal Inc., Waterloo, ON (CA)

(21) Appl. No.: 18/556,270

(22) PCT Filed: Apr. 21, 2022
(86) PCT No.: PCT/CA2022/050608

§ 371 Date: Oct. 19, 2023

Related U.S. Application Data
(60) Provisional application No. 63/177,586, filed on Apr. 21, 2021.

(51) Int. Cl. H01L 33/50; H01L 33/60

(52) U.S. Cl. CPC H01L 33/507; H01L 33/60; H01L 2933/0041

(57) ABSTRACT

The present invention discloses methods to integrate color conversion particle layers in different configurations in a microdevice. The microdevice has many device layers, and additionally comprises color conversion particles on a surface of the microdevice with a light coupling layer between the color conversion particles and the device layers. Further color conversion particles are one of nanowires or embedded quantum dots.

### FIELD OF THE INVENTION

The present invention pertains to a method of integrating color conversion material in a microdevice.

### SUMMARY

The present invention relates to a method of integrating color conversion material in a microdevice, the method comprising, having microdevice on a first substrate, having the microdevice comprising of device layers, having the microdevice additionally comprising of color conversion particles on at least one surface of the microdevice and having a light coupling layer between the color conversion particles and the device layers.

The present invention also relates to a method of integrating a color conversion material in a microdevice, the method comprising, forming a color conversion particle on a second substrate, and forming microdevice layers on top of the color conversion particles.

The present invention also relates to a method of integrating color conversion material in a microdevice, the method comprising, forming microdevice layers on a substrate and forming a color conversion particle on top of a device layer.

### BRIEF DESCRIPTION OF THE DRAWINGS

The foregoing and other advantages of the disclosure will become apparent upon reading the following detailed description and upon reference to the drawings.

FIG. 1A shows a microdevice shown that comprises device layers.

FIG. 1B shows the microdevice aligned with a system substrate where there is a bonding layer in the system substrate.

FIG. 1C shows the color conversion particles can be on the top or the bottom side.

FIG. 1D shows a seed layer is formed after the buffer layer.

FIG. 1E shows a device structure where a pad is formed on the top surface of the device.

While the present disclosure is susceptible to various modifications and alternative forms, specific embodiments or implementations have been shown by way of example in the drawings and will be described in detail herein. It should be understood, however, that the disclosure is not intended to be limited to the particular forms disclosed. Rather, the disclosure is to cover all modifications, equivalents, and alternatives falling within the spirit and scope of an invention as defined by the appended claims.

### DETAILED DESCRIPTION OF THE INVENTION

In this description, the terms “microdevice” and “device” are used interchangeably. However, it is clear to one skilled in the art that the embodiments described here are independent of the device size.

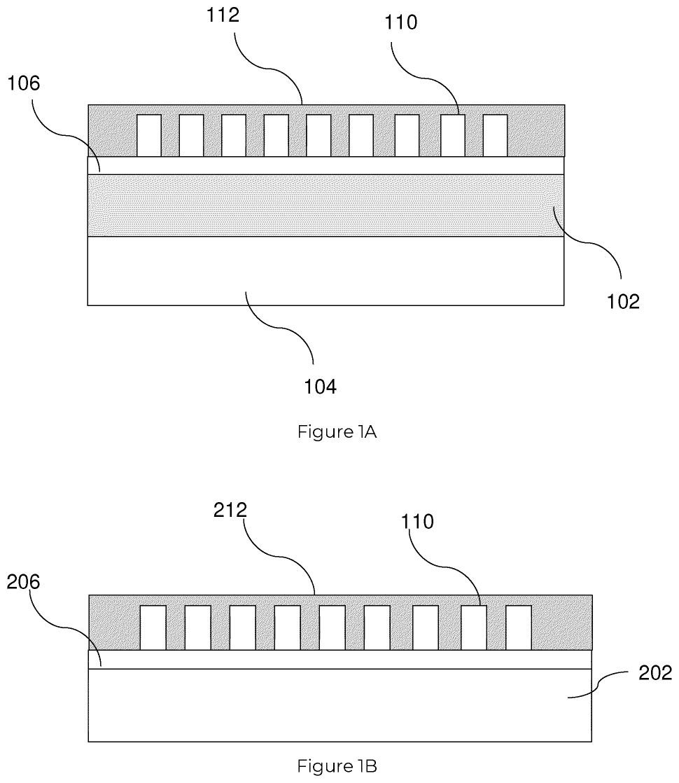

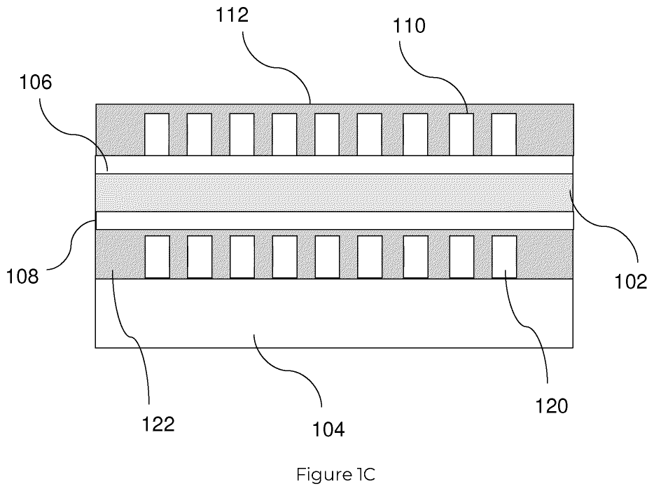

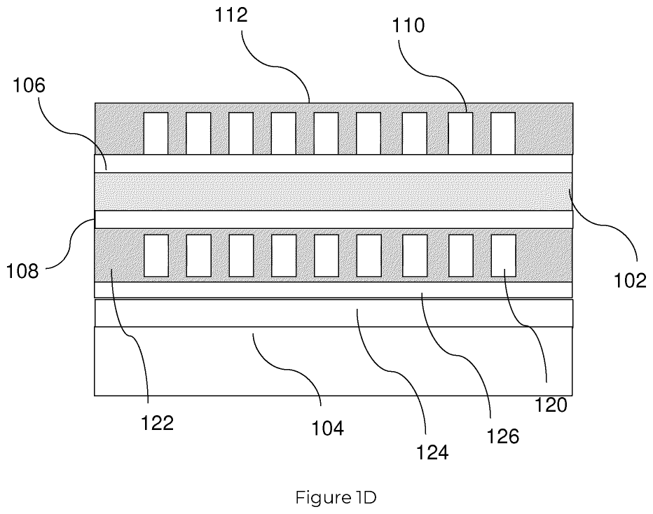

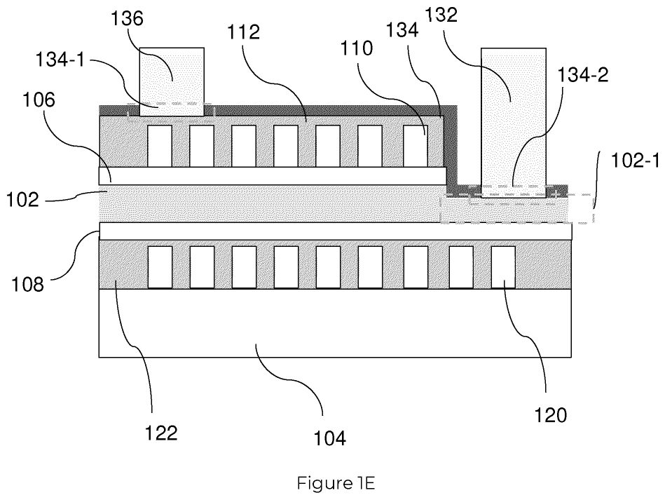

A microdevice shown in FIG. 1A comprises device layers (e.g., buffer, n layer, quantum well, p layer, blocking layers, and etc.). The microdevice can include color conversion particles 110 on one surface of the microdevice. There can be a light coupling layer 106 between the color conversion particles 110 and the device layers 102. In one case conductive layer 112 can be formed on top of the particles 110. In another case, layer 112 includes a passivation layer embedding the color conversion layer. In another case, layer 112 can be a passivation or conductive layer. In one case, the layer 112 may include a reflective layer. In this case, the lights generated by devices move through the color conversion particles 110 and reflect back by a reflective layer 112. The reflection can go through the particles 110 again and further enhance color conversion.

Device can be on a substrate 104. The substrate can be on either side of the device. FIG. 1A shows an example of the device and substrate. There can be other layers between the device layers and the substrate. If the substrate is on the other side, there can be other layers between the substrate and layer 112.

One method of developing color conversion particles 110 on top of the device is to grow the color conversion particle layer on a substrate 202 as shown on FIG. 1B and form microdevice layers on top of the color conversion layers. The particles 110 can be either nanowires, core-shell nanowire, embedded QD in the nanowire, and so on. The color conversion particles 110 can be formed on top of sacrificial layers 206. In one related case, the particles 110 are bonded on top of device layers 102 and separated from the original substrate 202. In another case, the particles 110 can be embedded in a film 212. The film 212 is separated from the original substrate 202 and bonded on top of the device layers. The layer 212 can be the same as layer 112 in the final structure.

In another method, the color conversion particles are grown on top of the device layers 102 (or optical coupling layer 106), wherein an optical coupling layer is formed between the color conversion particles and the microdevice layers. In one case, to form the particle, an ohmic layer is formed on top of the device layer. A dielectric layer can form on top of the device layers 102 (or 106), the dielectric is patterned to size and distribution of color conversion particles.

In another related case, the particles are formed directly on the device layers 102 (or 106) (dielectric or other seeding method can be used). The ohmic layer can be deposited after on top of the particles 110 and then space between the particles on the device layers. Then the ohmic layer can be annealed if needed. The ohmic layer can include several different sub layers.

In another related case, as shown in FIG. 1C, the color conversion particles 110 and 120 can be on the top or the bottom side. To form the particles 120 on the bottom side, the particles can form on the substrate 104 first. They can be embedded in layer 122. The layer 122 can be part of the device layers 102 such as buffer layer, doped layer, or combination of thereafter. There can be a light coupling layer 108 between the color conversion particles 120 and the device layer if the embedding layer 122 is different from the device layer 102.

One approach, buffer layer 124 can be formed on the substrate 104. A seed layer 126 is formed after the buffer layer 124 (FIG. 1D). Here the seed layer can be a dielectric layer with openings in the dielectric layer. In another related case, the seed layer is formed as islands (e.g., metal). The opening in the dielectric layer can be the size of a nanostructure.

FIG. 1E shows one example of device structure where a pad 136 formed on the top surface of the device. Here a dielectric layer 134 is formed to cover at least the top surface of the device and an opening 134-1 is formed to provide coupling access to the device layer. If the color conversion particles are on the top surface, the pad can form on top of the color conversion layer where there is a conductive layer 112 between the color conversion particles. In another case, the color conversion particles can be removed underneath the dielectric opening 134-1 and the pad formed on top of the device layer 102 or the ohmic layer 106. Another pad 132 can be formed on the same side and top side of the device. Where part of the device layer 102 is etched to provide access to another point of the device layers 102-1. A dielectric opening 134-2 can be formed on that surface.

In another related case, there can be color conversion particles on a side different than the side the first pad 136 is formed.

In another related case, there can be a second pad on a side different from the first pad 136 of the device.

In all the above cases, the color conversion particles (e.g., nanowires, QD in wire, etc.) can form on the device layers. Then the device layers can be etched into different mesa sizes to form devices.

### Method Aspects

The invention discloses a method of integrating color conversion material in a microdevice. The method comprises, having the microdevice on a first substrate; having the microdevice comprising of device layers; having the microdevice additionally comprising of color conversion particles on at least one surface of the microdevice and having a light coupling layer between the color conversion particles and the device layers. Here the first substrate is on either side of the microdevice. Further a conductive layer is formed on top of the color conversion particles. Furthermore, a passivation layer may embed the color conversion particle layer. In addition, the device layers may comprise one of a buffer layer, an n-layer, a quantum well, a p-layer and blocking layers.

The method further discloses that the conductive layer includes a reflective layer, and the passivation layer includes a reflective layer.

The method further discloses that the lights generated by the microdevice move through the color conversion particles and reflect back by the reflective layer and the reflection goes through the color conversion particles again further enhancing color conversion.

The invention further discloses a method of integrating a color conversion material in a microdevice, the method comprising, forming a color conversion particle on a second substrate, and forming microdevice layers on top of the color conversion particles. Here the color conversion particles are formed on top of sacrificial layers, wherein the color conversion particles are bonded on top of the device layers and separated from the second substrate and wherein further the color conversion particles are embedded in a film such that the film is separated from the second substrate and then bonded on top of the device layers.

The method further discloses, forming the color conversion particles includes a seed layer and deposition.

The method further discloses that the device layers include one of buffer layer, n-layer, quantum well, p-layer and other blocking layers.

The method further discloses that the color conversion particles are one of nanowires or embedded quantum dots.

The method further discloses that an optical coupling layer is formed between the color conversion particles and the microdevice layers. Here, to form the particle, an ohmic layer is formed on top of an ohmic layer, wherein the dielectric layer has an opening patterned to the size and distribution of color conversion particles.

The invention further discloses a method of integrating color conversion material in a microdevice, the method comprising, forming microdevice layers on a substrate and forming a color conversion particle on top of a device layer.

The method further discloses forming color conversion particles includes a first seed layer and deposition.

The method further discloses that device layers may include one of buffer layer, n-layer, quantum well, p-layer and other blocking layers. In addition, the color conversion particles may be one of nanowires or embedded quantum dots.

The method further discloses that an optical coupling layer is formed between the color conversion particles and the microdevice layers.

The method further discloses that the color conversion particles are on the bottom side of the device layers with the color conversion particles formed on the substrate first and embedded in an additional layer. Here the additional layer is part of the device layers comprising of a first buffer layer or a doped layer or combination of thereof. Further, there may be a light coupling layer between the color conversion particles and the device layers if the additional layer is different from the device layers. Furthermore, a second buffer layer may be formed on the substrate and a second seed layer is formed on the second buffer layer. In addition, the second seed layer may be a dielectric layer with openings wherein the opening in the dielectric layer may be the size of a nanostructure.

In addition, a pad may be formed on the top surface of the device and a second dielectric layer is formed to cover at least a top surface of the device and an opening is formed to provide coupling access to the device layer. Here, if the color conversion particles are on the top surface the pad can form on a top of the color conversion layer where there is a conductive layer between the color conversion particles. Here, as well, the color conversion particles can be removed underneath the dielectric opening and the pad is formed on top of the device layer or the ohmic layer. Here, as well, another pad may be formed on the same side of the device where part of the device layers are etched to provide access to another point of the device layers and a dielectric opening is formed on that surface.

The method further discloses that the color conversion particles may be on a side different from the side the first pad is formed.

The method further discloses that the second pad may be on a side different from the first pad of the device.

The foregoing description of one or more embodiments of the invention has been presented for the purposes of illustration and description. It is not intended to be exhaustive or to limit the invention to the precise form disclosed. Many modifications and variations are possible in light of the above teachings. It is intended that the scope of the invention be limited not by this detailed description, but rather by the claims appended hereto.

1. A method of integrating color conversion material in a microdevice, the method comprising:
having microdevice on a first substrate;
having the microdevice comprising of device layers;
having the microdevice additionally comprising of color conversion particles on at least one surface of the microdevice; and
having a light coupling layer between the color conversion particles and the device layers.

2. The method of claim 1, wherein the first substrate is on either side of the microdevice.

3. The method of claim 1, wherein a conductive layer is formed on top of the color conversion particles.

4. The method of claim 1, wherein a passivation layer embeds the color conversion particle layer.

5. The method of claim 3, wherein the conductive layer includes a reflective layer.

6. The method of claim 4, wherein the passivation layer includes a reflective layer.

7. The method of claim 6, wherein lights generated by the microdevice move through the color conversion particles and are reflected back by the reflective layer and the reflection goes through the color conversion particles again.

8. The method of claim 1, wherein the device layers comprise one of a buffer layer, an n-layer, a quantum well, a p-layer and blocking layers.

9. A method of integrating a color conversion material in a microdevice, the method comprising:
forming a color conversion particle on a second substrate; and
forming microdevice layers on top of the color conversion particles.

10. The method of claim 9, wherein the color conversion particles are formed on top of sacrificial layers.

11. The method of claim 10, wherein the color conversion particles are bonded on top of the device layers and separated from the second substrate.

12. The method of claim 11, wherein the color conversion particles are embedded in a film such that the film is separated from the second substrate and then bonded on top of the device layers.

13. The method of claim 9, wherein forming the color conversion particles includes a seed layer and deposition.

14. The method of claim 9, where device layers include one of buffer layer, n-layer, quantum well, p-layer and other blocking layers.

15. The method of claim 9, where the color conversion particles are one of nanowires or embedded quantum dots.

16. The method of claim 9, wherein an optical coupling layer is formed between the color conversion particles and the microdevice layers.

17. The method of claim 16, wherein to form the particle, an ohmic layer is formed on top of an ohmic layer, wherein the dielectric layer has an opening patterned to a size and a distribution of the color conversion particles.

18. (canceled)

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)
